(19) United States
(12) Patent Application Publication
(10) Pub. No.: US 2018/0040532 A1
(43) Pub. Date: Feb. 8, 2018

(54) HEAT SINK

(71) Applicant: HEWLETT-PACKARD DEVELOPMENT COMPANY, L.P., HOUSTON, TX (US)

(72) Inventors: KUAN-TING WU, TAIPEI CITY (TW); CHIENLUNG YANG, HOUSTON, TX (US); CHI-HAO CHANG, TAIPEI CITY (TW)

(21) Appl. No.: 15/542,886

(22) PCT Filed: Apr. 30, 2015
(86) PCT No.: PCT/US2015/028470

§ 371 Date: Jul. 11, 2017

(51) Int. Cl. H01L 23/367; G06F 1/20; H01L 23/373

(52) U.S. Cl. CPC H01L 23/3672; H01L 23/3731; H01L 23/3732; H01L 23/3735; G06F 1/20; H01L 23/3736

(57) ABSTRACT

Examples disclosed herein relate to a heat sink. Examples include a thermoconductive base thermally coupled to a device. Examples include a fin thermally coupled to and extending from a first surface of the thermoconductive base to dissipate heat generated by the device. Examples include a heat insulation layer disposed on a distal end of the fin to insulate the distal end of the fin from heat generated by the device.

### BACKGROUND

Electrical and mechanical devices may generate heat during operation. The heat generated during operation of a device may damage the device or make the device too hot to safely handle. Various methods of reducing the impact of generated heat have been devised. A heat sink is a device to absorb and dissipate generated heat from electrical and mechanical devices.

### BRIEF DESCRIPTION OF THE DRAWINGS

The following detailed description references the drawings, wherein:

FIG. 1 is a side view of an example heat dissipation system.

FIG. 2 is a side view of an example heat dissipation system.

FIG. 3 is a bottom perspective view of an example heat dissipation system of FIG.

FIG. 4 is a side view of an example heat dissipation system.

FIG. 5 is a side view of an example heat dissipation system,

FIG. 6 is a side view of an example heat dissipation system.

FIG. 7 is a side view of an example heat dissipation system,

FIG. 8 is a side perspective view of an example heat dissipation system of FIG. 1 depicting a heat dissipation pattern.

FIG. 9 is a side perspective view of n example silhouette of an electronic device including a heat dissipation system of FIG. 1.

FIG. 10 is a side perspective view of an example silhouette of an electronic device including a heat dissipation system of FIG. 1.

FIG. 11 is a rear view of an example computing device including a heat dissipation system.

### DETAILED DESCRIPTION

In the following discussion and in the claims, the term “couple” or “couples” is intended to include suitable indirect and/or direct connections. Thus, if a first component is described as being coupled to a second component that coupling may, for example, be: (1) through a direct electrical, mechanical, or thermal connection, (2) through an indirect electrical, mechanical, or thermal connection via other devices and connections, (3) through an optical electrical connection, (4) through a wireless electrical connection, and/or (5) another suitable coupling. The term approximately as used herein to modify a value is intended to be determined based on the understanding of one of ordinary skin in the art, and can, for example, mean plus or minus 10% of that value.

An “electronic device” may be any device operating under electrical power, such as, a display device, a computing device, etc. A “computing device” or “device” may be a desktop computer, laptop (or notebook) computer, workstation, tablet computer, mobile phone, smartphone, smart watch, smart wearable glasses, smart device, server, blade enclosure, imaging device, or any other processing device. An “imaging device” may be a hardware device, such as a printer, multifunction printer (MFP), or any other device with functionalities to physically produce graphical representation(s) (e.g., text, images, models etc.) on paper, photopolymers, thermopolymers, plastics, composite, metal, wood, or the like. In some examples, an MFP may be capable of performing a combination of multiple different functionalities such as, for example, printing, photocopying, scanning, faxing, etc.

A heat sink may be used to absorb and dissipate heat generated in an electrical or mechanical device. Some heat sinks operate by absorbing heat from heat generating devices or components and providing a large surface area from which the heat may be dissipated to a surrounding environment. In some heat sinks, a single or series of protrusions or fins may be used to provide a larger surface area from which heat may be dissipated to the surrounding environment. As the environment or area surrounding a heat sink absorbs dissipated heat, the temperature of that environment may increase. Heat sinks are often disposed in a device in a manner to dissipate heat to an area of the device or surrounding the device which will not be damaged by the dissipated heat or will not cause injury to an operator. However, as electrical and mechanical devices become smaller, there are fewer areas of the device or surrounding the device which will not be damaged by dissipated heat or cause injury to an operator.

To address these issues, in the examples described herein, a heat sink is described which reduces the ambient temperature of an area adjacent to or coupled to the heat sink to a range safe for human handling. In examples, the heat sink includes a heat insulation layer disposed on a distal end of a fin of the heat sink to reduce the ambient temperature surrounding the distal end of the fin. In such examples, the distal end of the fin may be of a lower temperature while the device is generating heat than in a heat sink without a heat insulation layer. In such an example, the heat sink may be disposed closer to or coupled to an outer surface of the device without increasing the temperature of the outer surface beyond a human safe range.

Referring now to the drawings, FIG. 1 is a side view, of an example heat dissipation system 100. In the example of FIG. 1, heat dissipation system 100 includes a thermoconductive base 110, a fin 120 extending from a surface of thermoconductive base 110, a device 150, and a heat insulation layer 130. In an example, heat insulation layer 130 may be disposed on a distal end of fin 120 to insulate the distal end of fin 120.

In some examples, device 150 may be any type of heat generating device, such as, a memory, a battery, a central processing unit (CPU), a component on a printed circuit board, such as, a resistor, a capacitor, a diode, an inductor, a transistor, an integrated circuit (IC), etc. In such examples, device 150 may be thermally coupled to thermoconductive base 110 to transfer heat to thermoconductive base 110. Thermoconductive base 110 may be comprised of any material to thermally conduct heat from a device coupled thereto. In some examples, thermoconductive base 110 may be comprised of a metal, a metal-alloy, a ceramic such as silicon carbide, etc.

In some examples, fin 120 may extend from a first surface of thermoconductive base 110 and device 150 may be coupled to a second surface of thermoconductive base 110 opposite the first surface. In an example, fin 120 may be extruded from the same material as thermoconductive base 110. In other examples, fin 120 may be comprised of any material to thermally conduct heat and may be coupled to thermoconductive base 110 by any mechanism, such as a bonding mechanism, (glue, soldering, etc.), a fastening mechanism (screw, etc.), etc. In some examples, a plurality of fins 120 may extend from thermoconductive base 110.

In some examples, heat insulation layer 130 may be comprised of any thermally insulating material to thermally insulate the distal end of fin 120. In some examples, heat insulation layer 130 may be comprised of at least one of fiberglass, mineral wool, mineral fiber, mineral cotton, mineral fibre, man-made mineral fibre (MMMF), man-made vitreous fiber (MMVF) glass wool, ceramic fibers, cellulose, calcium silicate, cellular glass, elastomeric foam, phenolic foam, vermiculite, polyurethane foam, polystyrene foam in polymeric resins (thermoplastic or thermoset resins), etc. In an example, heat insulation layer 130 may insulate the distal end of fin 120 from heat generated by device 150. In such an example, the amount of heat radiated by the distal end of fin 120 may be reduced thereby reducing an ambient temperature surrounding the distal end of fin 120 compared to an example in which there is no heat insulation layer 130. In some examples, between approximately 0.1 mm and approximately 10 mm of heat insulation layer 130 may be disposed on the distal end of fin 120.

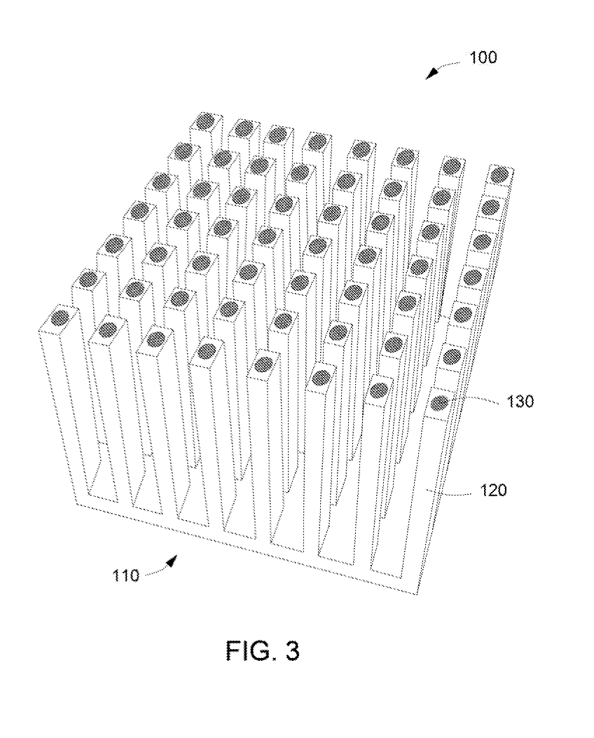

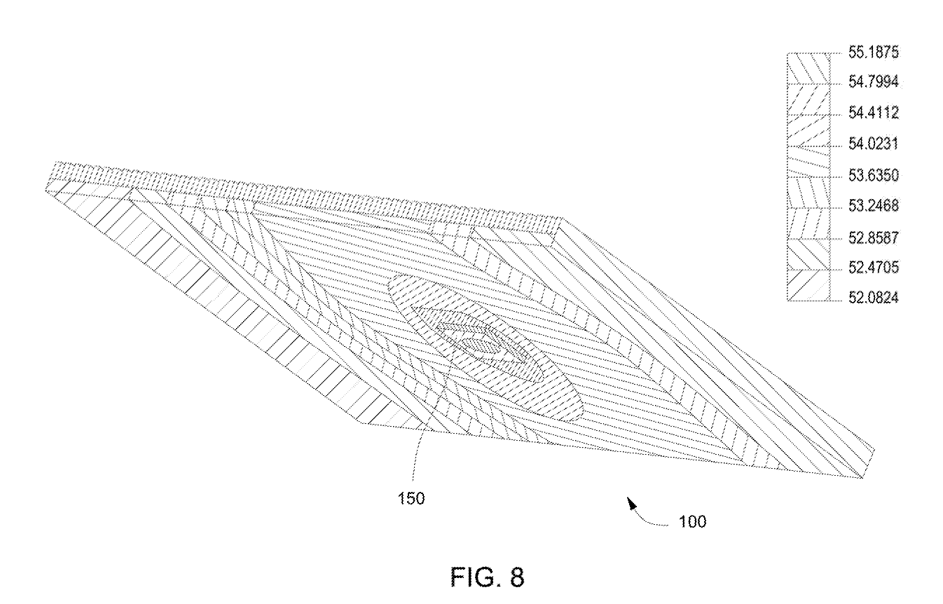

FIG. 3 is a bottom perspective view of example heat dissipation system 100 of FIG. 1. FIG. 8 is a side perspective view of heat dissipation system 100 depicting a heat dissipation pattern. In the example of FIG. 3, heat insulation layer 130 may be disposed on less than an entire surface area of the distal end of fin 120. In such an example, the ambient temperature surrounding the distal end of fin 120 may be reduced compared to an example in which there is no heat insulation layer 130. Although depicted as having a circular cross-section in the example of FIG. 3, heat insulation layer 130 may be of any cross-sectional shape to cover a portion of the distant end of fin 120. Furthermore, although FIG. 3 depicts a plurality of fins 120 with the same shaped deposition of heat insulation layer 130, the examples are not limited thereto and the shape of some or all of the depositions of heat insulation layer 130 on the plurality of fins 120 in FIG. 3 may be different from each other. In some examples, some of the plurality of fins 120 may have a depositions of heat insulation layer 130 with a surface area less than the entire surface area of the distal end of fin 120 and the others of the plurality of fins 120 may have depositions of heat insulation layer 130 that completely cover the distal end of fin 120. In the example of FIG. 8, the temperature of different areas of the heat dissipation system 100 are shown while device 150 is producing heat to be dissipated by heat dissipation system 100. As shown in FIG. 8, heat generated by device 150 may be radially dissipated (i.e., radially transferred away) from device 150. In the example of FIG. 8, the temperature of some of the distal ends of the plurality of fins 120 may remain within a human safe range of less than 110 degrees Fahrenheit.

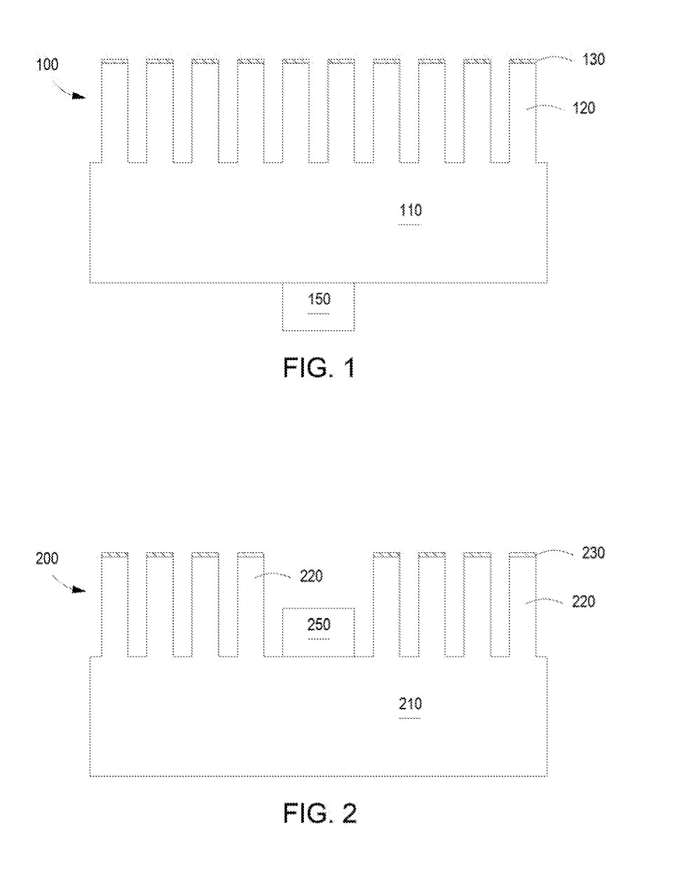

FIG. 2 is a side view of an example heat dissipation system 200. In the example of FIG. 2, heat dissipation system 200 includes a thermoconductive base 210, a fin 220 extending from a surface of thermoconductive base 210, a device 250, and a heat insulation layer 230. In an example, heat insulation layer 230 may be disposed on a distal end of fin 220 to insulate the distal end of fin 220.

In some examples, device 250 may be any type of heat, generating device, such as, a memory, a battery, a CPU, a component on a printed circuit board, such as, a resistor, a capacitor, a diode, an inductor, a transistor, an IC, etc. In such examples, device 250 may be thermally coupled to thermoconductive base 210 to transfer heat to thermoconductive base 210. Thermoconductive base 210 may be comprised of any material to thermally conduct heat from a device coupled thereto. In some examples, thermoconductive base 210 may be comprised of a metal, a metal-alloy, a ceramic such as silicon carbide, etc.

In some examples, fin 220 may extend from a first surface of thermoconductive base 210 and device 250 may be coupled to the first surface of thermoconductive base 210. In some examples, a plurality of fins 220 may extend from thermoconductive base 210. In the, example of FIG. 2, device 250 may be disposed in the center of the plurality of fins 220 on thermoconductive base 210. In other examples, device 250 may be disposed on any location of the first surface of thermoconductive base 210. In an example, fin 220 may be extruded from the same material as thermoconductive base 210. In other examples, fin 220 may be comprised of any material thermally conduct heat and may be coupled to thermoconductive base 210 by any mechanism such as, a bonding mechanism, (glue, soldering, etc.), a fastening mechanism (screw, etc.), etc.

In some examples, heat insulation layer 230 may be comprised of any thermally insulating material to thermally insulate the distal end of fin 220. In some examples, heat insulation layer 230 may be comprised of at least one of fiberglass, mineral wool, mineral fiber, mineral cotton, mineral fibre, MMMF, MMVF glass wool, ceramic fibers, cellulose, calcium silicate, cellular glass, elastomeric foam, phenolic foam, vermiculite, polyurethane foam, polystyrene foam in polymeric resins (thermoplastic or thermoset resins), etc. In an example, heat insulation layer 230 may insulate the distal end of fin 220 from heat generated by device 250. In such an example, the amount of heat radiated by the distal end of fin 220 may be reduced thereby reducing an ambient temperature surrounding the distal end of fin 220 compared to an example in which there is no heat insulation layer 230. In some examples, between approximately 0.1 mm and approximately 10 mm of heat insulation layer 230 may be disposed on the distal end of fin 220.

In some examples, heat insulation layer 230 may be disposed on less than an entire surface area of the distal end of fin 220 as described above with respect to FIG. 3. In such an example, the ambient temperature surrounding the distal end of fin 220 may be reduced compared with an example in which there is no heat insulation layer 230.

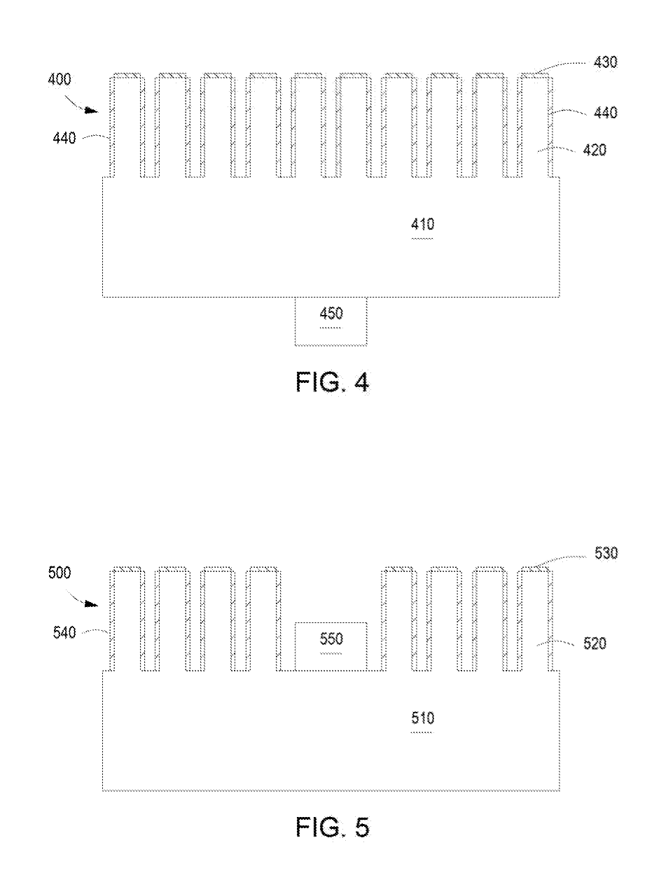

FIG. 4 is a side view of an example heat dissipation system 400. In the example of FIG. 4, heat dissipation system 400 includes a thermoconductive base 410, a fin 420 extending from a surface of thermoconductive base 410, a device 450, a heat insulation layer 430, and a heat radiation layer 440. In an example, heat insulation layer 430 may be disposed on a distal end of fin 420 to insulate the distal end of fin 420.

In some examples, device 450 may be any type of heat generating device, such as, a memory, a battery, a CPU, a component on a printed circuit board, such as, a resistor, a capacitor, a diode, an inductor, a transistor, an integrated circuit (IC), etc. In such examples, device 450 may be thermally coupled to thermoconductive base 410 to transfer heat to thermoconductive base 410. Thermoconductive base 410 may be comprised of any material to thermally conduct heat from a device coupled thereto. In some examples, thermoconductive base 410 may be comprised of a metal, a metal-alloy, a ceramic such as silicon carbide, etc.

In some examples, fin 420 may extend from a first surface of thermoconductive base 410 and device 450 may be coupled to a second surface of thermoconductive base 410 opposite the first surface. In an example, fin 420 may be extruded from the same material as thermoconductive base 410. In other examples, fin 420 may be comprised of any material thermally conduct heat and coupled to thermoconductive base 410 by any mechanism, such as, a bonding mechanism, (glue, soldering, etc.), a fastening mechanism (screw, etc.), etc. In some examples, a plurality of fins 420 may extend from thermoconductive base 410,

In some examples, heat insulation layer 430 may be comprised of any thermally insulating material to thermally insulate the distal end of fin 420. In some examples, heat insulation layer 430 may be comprised of at least one of fiberglass, mineral wool, mineral fiber, mineral cotton, mineral fibre, MMMF, MMVF glass wool, ceramic fibers, cellulose, calcium silicate, cellular glass, elastomeric foam, phenolic foam, vermiculite, polyurethane foam, polystyrene foam in polymeric resins (thermoplastic or thermoset resins), etc. In an example, heat insulation layer 430 may insulate the distal end of fin 420 from heat generated by device 450. In such an example, the amount of heat radiated by the distal end of fin 420 may be reduced thereby reducing an ambient temperature surrounding the distal end of fin 420 compared to an example in which there is no heat insulation layer 430. In some examples, between approximately 0.1 mm and approximately 10 mm of heat insulation layer 430 may be disposed on the distal end of fin 420.

In some examples, heat insulation layer 430 may be disposed on less than an entire surface area of the distal end of fin 420 as described above with respect to FIG. 3. In such an example, the ambient temperature surrounding the distal end of fin 420 may be reduced compared to an example in which there is no heat insulation layer 430.

In some examples, heat radiation layer 440 may be disposed on fin 420 except a distal end of fin 420 on which heat insulation layer 430 is disposed. In such an example, heat radiation layer 420 may thermally dissipate heat from the surfaces of fin 420 on which it is disposed. In some examples, heat radiation layer 440 may be comprised of at least one of graphene, carbon nanotube. graphite, diamond-like-carbon, etc. Heat radiation layer 440 may be deposited on fin 420 in any manner, such as, physical deposition or vapor deposition. In some examples, heat radiation layer 440 may be disposed on all of fin 420 and then removed from the distal end of fin 420 by any mechanism, such as, mechanical polishing, chemical polishing, physical etching, chemical etching, etc. In the example of FIG. 4, a rate of heat dissipation from fin 420 may be increased compared with an example in which no heat radiation layer 440 is disposed on fin 420. Although heat radiation layer 440 is depicted as disposed on fin 420 except a distal end thereof, the examples are not limited thereto and heat radiation layer 440 may be disposed on the first surface of thermoconductive base 410 to increase the rate of heat dissipation therefrom. In some examples, between approximately 1 μm and approximately 100 μm of heat radiation layer 440 may be disposed on fin 420 except a distal end thereof.

FIG. 5 is a side view of an example heat dissipation system 500. In the example of FIG. 5, heat dissipation system 500 includes a thermoconductive base 510, a fin 520 extending from a surface of thermoconductive base 510, a device 550, a heat insulation layer 530, and a heat radiation layer 540. In an example, heat insulation layer 530 may be disposed on a distal end of fin 520 to insulate the distal end of fin 520.

In some examples, device 550 may be any type of heat generating device, such as, a memory, a battery, a CPU, a component on a printed circuit board, such as, a resistor, a capacitor, a diode, an inductor, a transistor, an IC, etc. In such examples, device 550 may be thermally coupled to thermoconductive base 510 to transfer heat to thermoconductive base 510. Thermoconductive base 510 may be comprised of any material to thermally conduct heat from a device coupled thereto. In some examples, thermoconductive base 510 may be comprised of a metal, a metal-alloy, a ceramic such as silicon carbide, etc.

In some examples, fin 520 may extend from a first surface of thermoconductive base 510 and device 550 may be coupled to the first surface of thermoconductive base 510. In some examples, a plurality of fins 520 may extend from thermoconductive base 510. In the example of FIG. 5, device 550 may be disposed in the center of the plurality of fins 520 on thermoconductive base 510. In other examples, device 550 may be disposed on any location of the first surface of thermoconductive base 510. In an example, fin 520 may be extruded from the same material as thermoconductive base 510. In other examples, fin 520 may be comprised of any material to thermally conduct heat and may be coupled to thermoconductive base 510 by any mechanism, such as, a bonding mechanism, (glue, soldering, etc.), a fastening mechanism (screw, etc.), etc.

In some examples, heat insulation layer 530 may be comprised of any thermally insulating material to thermally insulate the distal end of fin 520. In some examples, heat insulation layer 530 may be comprised of at least one of fiberglass, mineral wool, mineral fiber, mineral cotton, mineral fibre, MMMF, MMVF glass wool, ceramic fibers, cellulose, calcium silicate, cellular glass, elastomeric foam, phenolic foam, vermiculite, polyurethane foam, polystyrene foam in polymeric resins (thermoplastic or thermoset resins), etc. In an example, heat insulation layer 530 may insulate the distal end of fin 520 from heat generated by device 550. In such an example, the amount of heat radiated by the distal end of fin 520 may be reduced thereby reducing an ambient temperature surrounding the distal end of fin 520 compared to an example in which there is no heat insulation layer 530. In some examples, between approximately 0.1 mm and approximately 10 mm of heat insulation layer 530 may be disposed on the distal end of fin 520.

In some examples, heat insulation layer 530 may be disposed on less than an entire surface area of the distal end of fin 520 as described above with respect to FIG. 3. In such an example, the ambient temperature surrounding the distal end of fin 520 may be reduced compared to an example in which there is no heat insulation layer 530.

In some examples, heat radiation layer 540 may be disposed on fin 520 except a distal end of fin 520 on which heat insulation layer 530 is disposed. In such an example, heat radiation layer 520 may thermally dissipate heat from the surfaces of fin 520 on which it is disposed. In some examples, heat radiation layer 540 may be comprised of at least one of graphene, carbon nanotube, graphite, and diamond-like-carbon, etc. Heat radiation layer 540 may be deposited on fin 520 in any manner, such as, physical deposition or vapor deposition. In some examples, heat radiation layer 540 may be disposed on all of fin 520 and then removed from the distal end of fin 520 by any mechanism, such as, mechanical polishing, chemical polishing, physical etching, chemical etching, etc. In the example of FIG. 5, a rate of heat dissipation from fin 520 may be increased compared with an example in which no heat radiation layer 540 is disposed on fin 520. Although heat radiation layer 540 is depicted as disposed on only on fin 520 except a distal end of fin 520, the examples are not limited thereto and heat radiation layer 540 may be disposed on a portion of the first surface of thermoconductive base 510 not occupied by device 540 to increase the rate of heat dissipation. In some examples, between approximately 1 μm and approximately 100 μm of heat radiation layer 540 may be disposed on fin 520 except a distal end thereof.

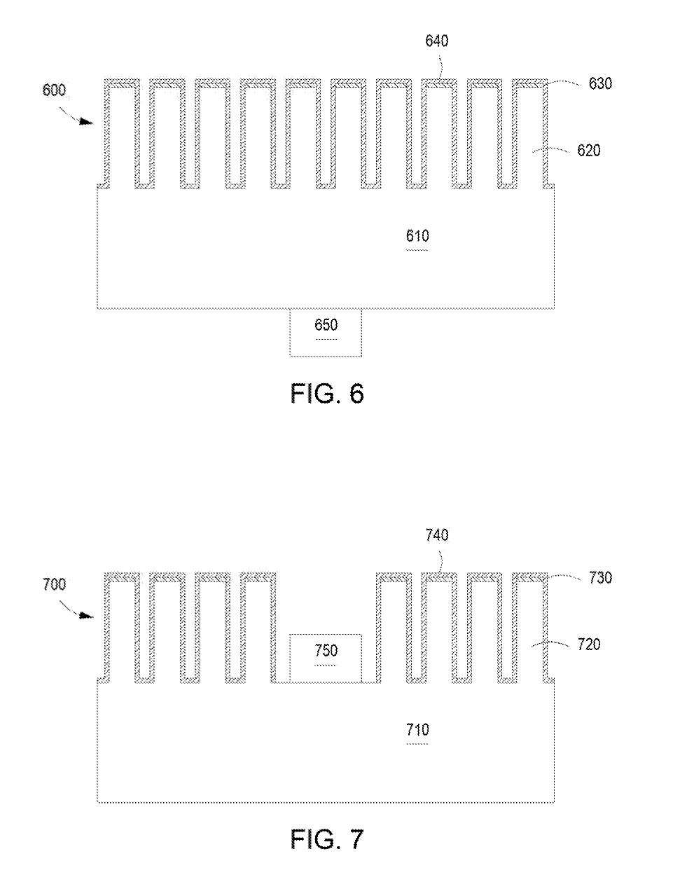

FIG. 6 is a side view of an example heat dissipation system 600. In the example of FIG. 6, heat dissipation system 600 includes a thermoconductive base 610, a fin 620 extending from a surface of thermoconductive base 610, a device 650, a heat insulation layer 630, and a heat radiation layer 640. In an example, heat insulation layer 630 may be disposed on a distal end of tin 620 to insulate the distal end of fin 620.

In some examples, device 650 may be any type of heat generating device, such as, a memory, a battery, a CPU, a component on a printed circuit board, such as, a resistor, a capacitor, a diode, an inductor, a transistor, an IC, etc. In such examples, device 650 may be thermally coupled to thermoconductive base 610 to transfer heat to thermoconductive base 610. Thermoconductive base 610 may be comprised of any material to thermally conduct heat from a device coupled thereto. In some examples, thermoconductive base 610 may be comprised of a metal, a metal-alloy, a ceramic such as silicon carbide, etc.

In some examples, fin 620 may extend from a first surface of thermoconductive base 610 and device 650 may be coupled to a second surface of thermoconductive base 610 opposite the first surface. In an example, fin 620 may be extruded from the same material as thermoconductive base 610. In other examples, fin 620 may be comprised of any material to thermally conduct heat and may be coupled to thermoconductive base 610 by any mechanism, such as, a bonding mechanism, (glue, soldering, etc.), a fastening mechanism (screw, etc.), etc. In some examples, a plurality of fins 620 may extend from thermoconductive base 610.

In some examples, heat insulation layer 630 may be comprised of any thermally insulating material to thermally insulate the distal end of fin 620. In some examples, heat insulation layer 630 may be comprised of at least one of fiberglass, mineral wool, mineral fiber, mineral cotton, mineral fibre, MMMF, MMVF glass wool, ceramic fibers, cellulose, calcium silicate, cellular glass, elastomeric foam, phenolic foam, vermiculite, polyurethane foam, polystyrene foam in polymeric resins (thermoplastic or thermoset resins). In an example, heat insulation layer 630 may insulate the distal end of fin 620 from heat generated by device 650. In such an example, the amount of heat radiated by the distal end of fin 620 may be reduced thereby reducing an ambient temperature surrounding the distal end of fin 620 compared to an example in which there is no heat insulation layer 630. In some examples, between approximately 0.1 mm and approximately 10 mm of heat insulation layer 630 may be disposed on the distal end of fin 620.

In some examples, heat insulation layer 630 may be disposed on less than an entire surface area of the distal end of fin 620 as described above with respect to FIG. 3. In such an example, the ambient temperature surrounding the distal end of fin 620 may be reduced compared to an example in which there is no heat insulation layer 630.

In some examples, heat radiation layer 640 may be disposed on thermoconductive base 610 and fin 620 including on heat insulation layer 630 disposed on the distal end of fin 620. In such an example, heat radiation layer 640 may thermally dissipate heat from thermoconductive base 610 and fin 620. In some examples, heat radiation layer 640 may be comprised of at least one of graphene, carbon nanotube, graphite, and diamond-like-carbon, etc. Heat radiation layer 640 may be deposited on thermoconductive base 610 and fin 620 in any manner, such as, physical deposition or vapor deposition. In the example of FIG. 6, a rate of heat dissipation from thermoconductive base 610 and fin 620 may be increased compared with an example in which no heat radiation layer 640 is disposed on thermoconductive base 610 and fin 620. Although heat radiation layer 640 is depicted as disposed on the first surface of thermoconductive base 610 and fin 620, the examples are not limited thereto and heat radiation layer 640 may be disposed only on fin 620 or thermoconductive base 610 to increase the rate of heat dissipation therefrom. In some examples, between approximately 1 μm and approximately 100 μm of heat radiation layer 640 may be disposed on thermoconductive base 610 and fin 620.

FIG. 7 is a side view of an example heat dissipation system 700. In the example of FIG. 7, heat dissipation system 700 includes a thermoconductive base 710, a fin 720 extending from a surface of thermoconductive base 710, a device 750, a heat insulation layer 730, and a heat radiation layer 740. In an example, heat insulation layer 730 may be disposed on a distal end of fin 720 to insulate the distal end of fin 720.

In some examples, device 750 may be any type, of heat generating device, such as, a memory, a battery, a CPU, a component on a printed circuit board, such as, a resistor, a capacitor, a diode, an inductor, a transistor, an IC, etc. In such examples, device 750 may be thermally coupled to thermoconductive base 510 to transfer heat to thermoconductive base 710. Thermoconductive base 710 may be comprised of any material to thermally conduct heat from a device coupled thereto. In some examples, thermoconductive base 710 may be comprised of a metal, a metal-alloy, a ceramic such as silicon carbide, etc.

In some examples, fin 720 may extend from a first surface of thermoconductive base 710 and device 750 may be coupled to the first surface of thermoconductive base 710. In some examples, a plurality of fins 720 may extend from thermoconductive base 710. In the example of FIG. 7, device 750 may be disposed in the center of the plurality of fins 720 on thermoconductive base 710. In other examples, device 750 may be disposed on any location of the first surface of thermoconductive base 710. In an example, fin 720 may be extruded from the same material as thermoconductive base 710. In other examples, fin 720 may be comprised of any material to thermally conduct heat and may be coupled to thermoconductive base 710 by any mechanism, such as, a bonding mechanism, (glue, soldering, etc.), a fastening mechanism (screw, etc.), etc.

In some examples, heat insulation layer 730 may be comprised of any thermally insulating material to thermally insulate the distal end of fin 720. In some examples, heat insulation layer 730 may be comprised of at least one of fiberglass, mineral wool, mineral fiber, mineral cotton, mineral fibre, MMMF, MMVF glass wool, ceramic fibers, cellulose, calcium silicate, cellular glass, elastomeric foam, phenolic foam, vermiculite, polyurethane foam, polystyrene foam in polymeric resins (thermoplastic or thermoset resins). In an example, heat insulation layer 730 may insulate the distal end of fin 520 from heat generated by device 750. In such an example, the amount of heat radiated by the distal end of fin 520 may be reduced thereby reducing an ambient temperature surrounding the distal end of fin 720 compared to an example in which there is no heat insulation layer 730. In some examples, between approximately 0.1 mm and approximately 10 mm of heat insulation layer 630 may be disposed on the distal end of fin 620.

In some examples, heat insulation layer 730 may be disposed on less than an entire surface area of the distal end of fin 720 as described above with respect to FIG. 3. In such an example, the ambient temperature surrounding the distal end of fin 720 may be reduced compared to an example in which there is no heat insulation layer 730.

In some examples, heat radiation layer 740 may be disposed on thermoconductive base 710, except an area surrounding device 750 and under device 750, and fin 720. In such an example, heat radiation layer 740 may thermally dissipate heat from the portions of thermoconductive base 710 on which it is disposed and fin 720. In some examples, heat radiation layer 740 may be comprised of at least one of graphene, carbon nanotube, graphite, and diamond-like-carbon, etc. Heat radiation layer 740 may be deposited on thermoconductive base 710 and fin 720 in any manner, such as, physical deposition or vapor deposition. In the example of FIG. 7, a rate of heat dissipation from thermoconductive base 710 and fin 720 may be increased compared with an example in which no heat radiation layer 740 is disposed on thermoconductive base 710 and fin 720. Although heat radiation layer 740 is depicted as disposed on the first surface of thermoconductive base 710 and fin 720, the examples are not limited thereto and heat radiation layer 740 may be disposed only on fin 720 or thermoconductive base 710 to increase the rate of heat dissipation therefrom. In some examples, between approximately 1 μm and approximately 100 μm of heat radiation layer 740 may be disposed on thermoconductive base 710 and fin 720.

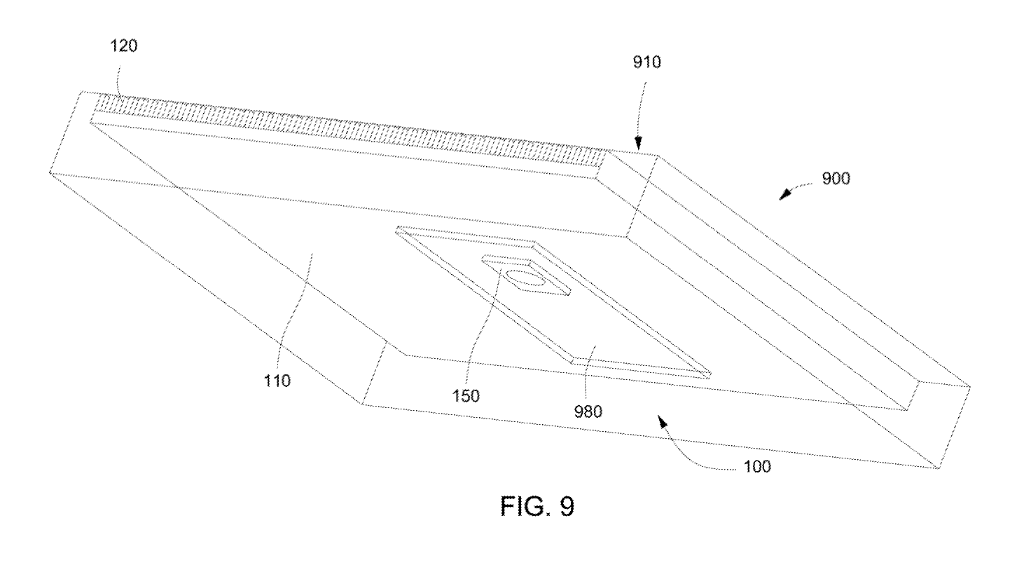

FIG. 9 is a side perspective view of an example silhouette of an electronic device 900 including a heat dissipation system 100. In an example, electronic device 900 may be any electronic device including a circuit board 980 on which a device 150 may be disposed. In an example, electronic device 900 may be a monitor, display, television, etc. Circuit board 980 may be coupled to a surface of thermoconductive base 110 opposite a surface from which a plurality of fins 120 extend. Heat insulation layer 130 may be disposed on a distal end of fins 120. Electronic device 900 may include a first surface 910 coupled to the distal end of fins 120. In such an example, as described above with respect to FIG. 1, the ambient temperature surrounding the distal end of fin 120 may be reduced compared to an example in which there is no heat insulation layer 130. In such an example, first surface 910 of electronic device 900 may remain at a lower temperature compared to an example in which there is no heat insulation layer 130. In such an example, the temperature of first surface 910 may remain within a temperature range that is suitable for human contact while device 150 is generating heat. Although electronic device 900 is depicted including heat dissipation system 100, any of heat dissipation systems 200 and 400-700 may be included in the electronic device 900. In such examples, the temperature of first surface 910 may remain within a temperature range that is suitable for human contact while a device coupled thereto is generating heat.

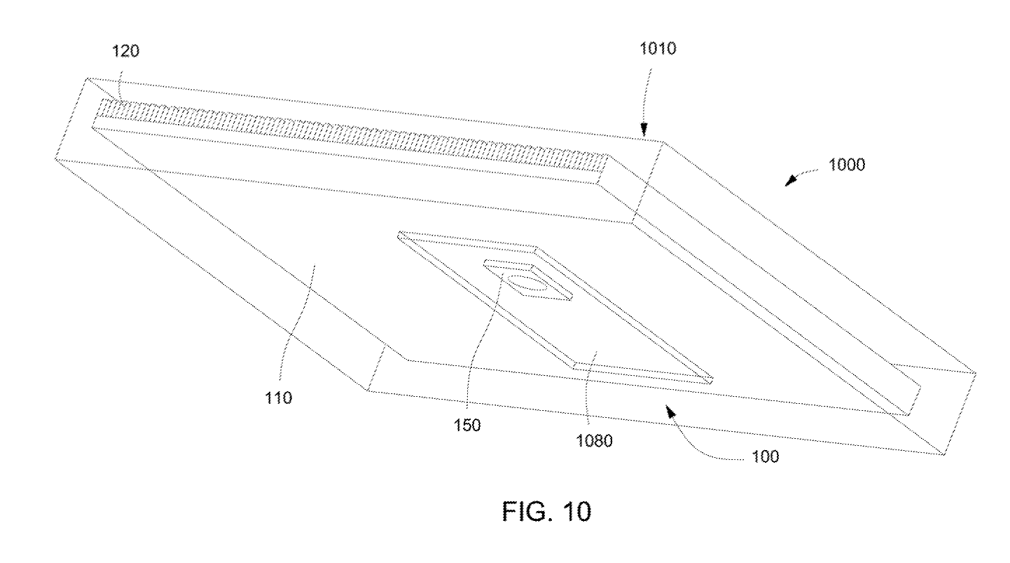

FIG. 10 is a side perspective view of an example silhouette of an electronic device 1000 including a heat dissipation system 100. In an example, electronic device 1000 may be any electronic device including a circuit board 1080 on which a device 150 may be disposed. In an example, electronic device 1000 may be a monitor, display, television, etc. Circuit board 1080 may be coupled to a surface of heat insulation layer 130 opposite a surface of thermoconductive base 110 from which a plurality of fins 120 extend. Heat insulation layer 130 may be disposed on a distal end of fins 120. Electronic device 1000 may include a first surface 1010 adjacent to a distal end of fins 120 on which heat insulation layer 130 is disposed. In such an example, first surface 1010 of electronic device 1000 may remain at a lower temperature compared to an example in which there is no heat insulation layer 130 on the distal end of fins 120. In such an example, the temperature of first surface 1010 may remain within a temperature range that is suitable for human contact while device 150 is generating heat. Although electronic device 1000 is depicted including heat dissipation system 100, any of heat dissipation systems 200 and 400-700 may be included in the electronic device 1000. In such examples, the temperature of first surface 1010 may remain within a temperature range that is suitable for human contact while a device coupled thereto is generating heat.

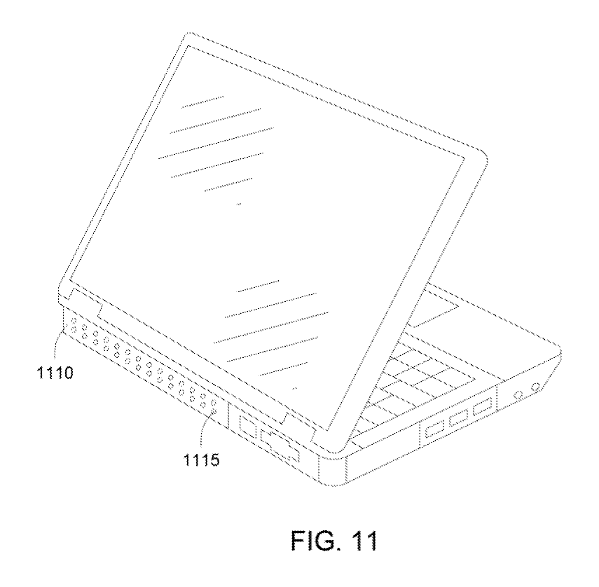

FIG. 11 is a rear view of an example computing device 1100 including a heat dissipation system. In an example, computing device 1100 may be any computing device including a heat dissipation system, such as, heat dissipation systems 100, 200, and 400-700 described above. In FIG. 11, computing device 1100 may include a first surface 1110 disposed adjacent to a heat dissipation system (not shown) which includes holes 1115 to expel air to an external environment. In the example of FIG. 11, first surface 1110 and/or air expelled from holes 115 may remain within a temperature range safe for human contact while computing device 1100 generates heat because a heat dissipation system therein includes a heat insulation layer disposed adjacent to or in contact with first surface 1100.

While certain implementations have been shown and described above, various changes in form and details may be made. For example, some features that have been described in relation to one implementation and/or process can be related to other implementations. In other words, processes, features, components, and/or properties described in relation to one implementation can be useful in other implementations. Furthermore, it should be understood that the systems, apparatuses, and methods described herein can include various combinations and/or sub-combinations of the components and/or features of the different implementations described. Thus, features described with reference to one or more implementations can be combined with other implementations described herein.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. A heat sink, comprising:
a thermoconductive base thermally coupled to a device;
at least one fin thermally coupled to and extending from a first surface of the thermoconductive base to dissipate heat generated by the device; and
a heat insulation layer disposed on a distal end of the at least one fin to insulate the distal end of the at least one fin from the heat generated by the device.

2. The heat sink of claim 1, further comprising a heat radiation layer disposed on the thermoconductive base and the fin to thermally dissipate the heat generated by the device.

3. The heat sink of claim 1, v Therein the device is disposed on the first surface.

4. The heat sink of claim 1, wherein the device is disposed on a second surface opposite the first surface.

5. The heat sink of claim 1, wherein the heat insulation layer comprises at least one of fiberglass, mineral wool, mineral fiber, mineral cotton, mineral fibre, man-made mineral fibre (MMMF), man-made vitreous fiber (MMVF) glass wool, ceramic fibers, cellulose, calcium silicate, cellular glass, elastomeric foam, phenolic foam, vermiculite, polyurethane foam, and polystyrene foam in polymeric resins.

6. The heat, sink of claim 2, wherein the heat radiation layer comprises at least one of graphene, carbon nanotube, graphite, and diamond like carbon.

7. An electronic device, comprising:
a heat generating component thermally coupled to a heat sink to transfer heat radially away from the heat generating component;
a first surface of the electronic device disposed adjacent to a distal end of a plurality of fins extending from the heat sink; and
a heat insulation layer disposed on the distal end of the plurality of fins to reduce the transfer of heat from the distal end of the plurality of fins of the heat sink to the first surface.

8. The electronic device of claim 7, further comprising a ventilation hole in the first surface of the electronic device to expel air.

9. The electronic device of claim 7, wherein the first surface and the distal end of the plurality of fins are coupled to each other.

10. The electronic device of claim 7, wherein the heat generating component is coupled to a second surface of the heat sink, and the plurality of fins extends from a first surface of the heat sink opposite the second surface.

11. A computing device, comprising:
a housing to house a heat generating device;
a heat sink thermally coupled to the heat generating device;
a heat dissipation structure extruded from the heat sink to dissipate heat from the heat generating device;
wheat radiation layer disposed on the heat dissipation structure to thermally dissipate heat therefrom; and
a heat insulation layer disposed on a distal end of the heat dissipation structure to reduce heat transfer to a first surface of the housing from the heat generating device,
wherein the thermal insulation layer is disposed on the heat radiation layer on the distal end of the heat dissipation structure.

12. The computing device of claim 11, wherein the heat dissipation structure includes a plurality of fins.

13. The computing device of claim 11, wherein the heat insulation layer comprises at least one of fiberglass, mineral wool, mineral fiber, mineral cotton, mineral fibre, man-made mineral fibre (MMMF), man-made vitreous fiber (MMVF) glass wool, ceramic fibers, cellulose, calcium silicate, cellular glass, elastomeric foam, phenolic foam, vermiculite, polyurethane foam, and polystyrene foam in polymeric resins.

14. The computing device of claim 11, wherein the heat radiation layer comprises at least one of graphene, carbon nanotube, graphite, and diamond like carbon.

15. The computing device of claim 11, further comprising a ventilation hole in the housing to expel air.
